(19) United States
(12) Patent Application Publication
(10) Pub. No.: US 2026/0159742 A1
(43) Pub. Date: Jun. 11, 2026

(54) SEMICONDUCTOR ENCAPSULATION COMPOSITION AND SEMICONDUCTOR PACKAGE INCLUDING A SEMICONDUCTOR ENCAPSULATION STRUCTURE FORMED THEREFROM

(71) Applicant: Samsung Electronics Co., Ltd., Suwon-si (KR)

(72) Inventor: Taehyung LEE, Suwon-si (KR)

(21) Appl. No.: 19/241,942

(22) Filed: Jun. 18, 2025

(30) Foreign Application Priority Data
Dec. 10, 2024 (KR) 10-2024-0182393

(51) Int. Cl. C09K 5/14; C08K 9/02; C09D 7/62; H01L 23/29

(52) U.S. Cl. CPC C09K 5/14; C09D 7/62; H10W 74/473; C08K 9/02; C08K 2201/001

(57) ABSTRACT

Provided is a semiconductor encapsulation composition including a high heat dissipation resin, a curing agent, and a first filler. The first filler includes a plurality of particles, each particle having a diamond particle core and a shell surrounding the diamond particle core, in which the shell includes at least one of alumina, magnesium oxide, aluminum nitride or boron nitride.

### CROSS-REFERENCE TO RELATED APPLICATIONS

This U.S. non-provisional patent application claims priority under 35 U.S.C. § 119 of Korean Patent Application No. 10-2024-0182393, filed on Dec. 10, 2024, the entire contents of which are hereby incorporated by reference.

### BACKGROUND

The present disclosure herein relates to a semiconductor encapsulation composition and a semiconductor package including a semiconductor encapsulation structure formed therefrom.

A recent trend toward miniaturization and higher functionality of an electronic device has required a higher density of a semiconductor package. A large amount of heat is generated inside the semiconductor package due to the higher density thereof, and thus semiconductor performance may be deteriorated. Accordingly, there is a growing interest in that the semiconductor package dissipates the heat generated inside the semiconductor package thereoutside. The heat generated inside the semiconductor package is dissipated to the outside thereof through a filling composition, and an epoxy molding compound (EMC), a die-attach film (DAF) and an underfill may be used as the filling composition of the semiconductor package. Accordingly, thermal conductivity of the filling composition is attracting attention.

### SUMMARY

The present disclosure provides a semiconductor encapsulation composition with improved thermal conductivity and flowability.

The present disclosure also provides a semiconductor package including a semiconductor encapsulation structure, with improved thermal conductivity and dissipation characteristics, formed from a semiconductor encapsulation composition.

A technical goal of the inventive concept is not limited to the goal mentioned above, and other technical goals that are not mentioned may be clearly understood from description below by those skilled in the art.

An embodiment of the inventive concept provides a semiconductor encapsulation composition including a high heat dissipation resin, a curing agent, and a first filler including a plurality of particles, each particle having a diamond particle core and a shell surrounding the diamond particle core, in which the shell includes at least one material selected from alumina, magnesium oxide, aluminum nitride or boron nitride.

In an embodiment of the inventive concept, a semiconductor encapsulation composition includes a high heat dissipation resin, a curing agent, and a first filler including a plurality of particles, each particle having a diamond particle core and a shell surrounding the diamond particle core, in which the shell includes a high heat dissipation inorganic material, and in which a thickness of the shell is equal to or greater than 1/10 of a diameter of the diamond particle core, and is equal to or greater than about 1 μm.

In an embodiment of the inventive concept, a semiconductor package includes a package substrate, a semiconductor chip on the package substrate, and a semiconductor encapsulation composition covering the semiconductor chip, wherein the semiconductor encapsulation composition includes a polymer matrix, and a first filler dispersed in the polymer matrix, and wherein the first filler includes a plurality of particles, each particle having a diamond particle core and a shell surrounding the diamond particle core, in which the shell includes at least one material selected from alumina, magnesium oxide, aluminum nitride or boron nitride.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a semiconductor package including a semiconductor encapsulation structure according to embodiments of the inventive concept;

FIG. 2 is an enlarged diagram of EV1 of FIG. 1;

FIG. 3 is an enlarged diagram corresponding to EV1 of FIG. 1;

FIG. 4A is a diagram schematically illustrating a first filler;

FIG. 4B is a diagram schematically illustrating a cross-section of a first filler;

FIG. 5 is a picture conceptually illustrating fluidity of a first polymer resin around a first filler;

FIG. 6 is a graph illustrating thermal conductivities of semiconductor encapsulation structures formed according to Comparative Example 1, Comparative Example 2, Comparative Example 3 and Example 1;

FIG. 7 is a graph illustrating thermal conductivities of semiconductor encapsulation structures prepared by using a first filler and a second filler together as fillers; and

FIG. 8 is a diagram illustrating a semiconductor package according to some embodiments.

### DETAILED DESCRIPTION

Hereinafter, a semiconductor encapsulation composition according to the inventive concept and a semiconductor package including a semiconductor encapsulation structure formed therefrom, will be described with reference to the drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, elements, and/or components, but do not preclude the presence or addition of one or more other features, elements, components, and/or groups thereof.

It will be understood that, although the terms “first” and “second”, etc. may be used herein to describe various elements or components, these elements or components should not be limited by these terms. Unless the context indicates otherwise, these terms are only used to distinguish one element or component from another element or component, for example as a naming convention. Thus, a first element or component discussed herein in one section of the specification could be termed a second element or component in another section of the specification or in the claims without departing from the teachings of the present invention. In addition, in certain cases, even if a term is not described using “first,” “second,” etc., in the specification, it may still be referred to as “first” or “second” in a claim to distinguish different claimed elements from each other.

The term “same,” as used herein when referring to a structure or region does not necessarily mean an exactly identical structure or region, but is intended to encompass a nearly identical structure or region within typical variations that may occur resulting from conventional manufacturing processes. The term “substantially” may be used herein to emphasize this meaning, unless the context or other statements indicate otherwise. The term “sphere” or “spherical shape” as used herein is intended to encompass both exact spherical shapes and near spherical shapes.

As used herein the terms “over”, “cover” or “covering” are intended to mean that an element is over or aside another element. The elements may be touching or not. An element “covering” another element need not cover an entire element to be considered “covering”. The terms are intended to encompass one element “covering” all, or any part of, an element below it.

As used herein, the words “surround”, “surrounding” and “surrounded” are intended to mean that an element is outside the other element. The elements may be touching or not. The surrounding element may or may not completely surround an inner element. The semiconductor encapsulation composition according to the inventive concept may be defined as an epoxy molding compound (EMC). For example, the semiconductor encapsulation composition may be a semiconductor package filling composition. Resins may be polymerized by using a monomer having a molecular weight of about 50 g/mol to about 1000 g/mol, or about 100 g/mol to about 900 g/mol. For example, the semiconductor encapsulation composition may have a powder form.

The semiconductor encapsulation composition may include a first polymer resin, a curing agent, an additive and a first filler. The first polymer resin may be, for example, an epoxy resin. In the present specification, the first polymer resin may be referred to as a high heat dissipation resin. A high heat dissipation resin may be a resin formulated to effectively transfer and disperse heat away from its source, preventing overheating. This is achieved by incorporating materials with high thermal conductivity.

The high heat dissipation resin may have for example, one mesogen unit as in Formula 1, or two mesogen units as in Formula 2. The high heat dissipation resin having the mesogen unit may have high molecular orientation and crystallinity. The greater the number of mesogen units in the high heat dissipation resin, the higher the molecular orientation.

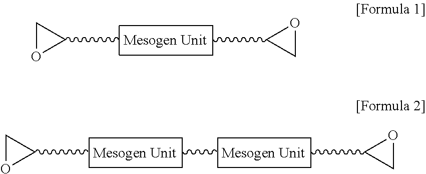

The mesogen unit included in the high heat dissipation resin may include a polymer compound illustrated in Formula 3A, Formula, 3B, Formula 3C, Formula 3D, Formula 3E, Formula 3F, Formula 3G, or Formula 3H. A substituent illustrated in the polymer compound may be one of hydrogen (H), chlorine (Cl) or a methyl group (CH₃)

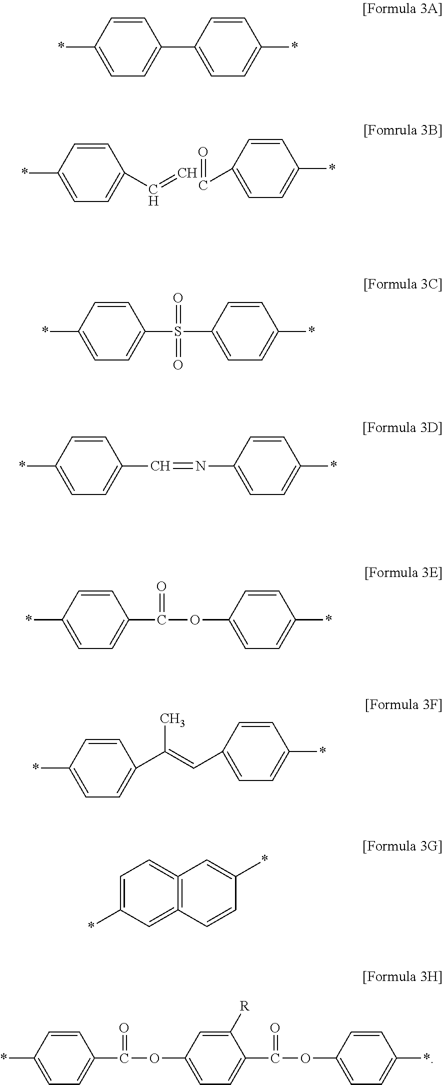

A compositional ratio of the high heat dissipation resin may be about 2 wt % to about 10 wt %, or about 3 wt % to 9 wt %, with respect to the total amount of the semiconductor encapsulation composition.

According to some embodiments, the semiconductor encapsulation composition may further include a second polymer resin. The second polymer resin may be, for example, an epoxy resin. In example embodiments, the second polymer resin is an epoxy resin, such as the first polymer resin, but may include a different material from the first polymer resin. The second polymer resin may be referred to as a “normal resin,” as compared to the first polymer resin.

The second polymer resin may include a thermosetting polymer. The thermosetting polymer may be at least one polymer selected from the group consisting of an epoxy-based polymer and a bismaleimide-based polymer.

For example, the epoxy-based polymer may be one or more of bisphenol A epoxy resin, bisphenol F epoxy resin, naphthalene epoxy resin, aminophenol epoxy resin, hydrated bisphenol epoxy resin, alicyclic epoxy resin, alcohol ether epoxy resin, alicyclic aliphatic epoxy resin, fluorene epoxy resin, siloxane-based epoxy resin, or the like, but the inventive concept is not limited thereto. These may be used alone, or at least two thereof may be mixed and used.

The bismaleimide-based polymer may be a polymer obtained by polymerization of a maleimide monomer including one or more maleimide groups or two or more maleimide groups. For example, the maleimide monomer may be N-phenylmaleimide, N-(2-methylphenyl)maleimide, N-(4-methylphenyl)maleimide, N-(2,6-dimethylphenyl)maleimide, bis(4-maleimidophenyl)methane, 2,2-bis(4-(4-maleimidophenoxy)-phenyl)propane, bis(3,5-dimethyl-4-maleimidophenyl)methane, bis(3-ethyl-5-methyl-4-maleimidophenyl)methane, bis(3,5-diethyl-4-maleimidophenyl)methane, polyphenylmethanebismaleimide, other maleimides including a biphenyl structure, or the like, but the inventive concept is not limited thereto. In addition, the bismaleimide-based polymer may be obtained from a prepolymer including a maleimide group. For example, the prepolymer may be an arbitrary one, a mixture of at least two, or the like of N-phenylmaleimide prepolymer, N-(2-methylphenyl)maleimide prepolymer, N-(4-methylphenyl)maleimide prepolymer, N-(2,6-dimethylphenyl)maleimide prepolymer, bis(4-maleimidophenyl)methane prepolymer, 2,2-bis(4-(4-maleimidophenoxy)-phenyl)propane prepolymer, bis(3,5-dimethyl-4-maleimidophenyl)methane prepolymer, bis(3-ethyl-5-methyl-4-maleimidophenyl)methane prepolymer, bis(3,5-diethyl-4-maleimidophenyl)methane prepolymer, polyphenylmethane bismaleimide prepolymer, maleimide prepolymer containing a biphenyl structure, prepolymer of N-phenyl maleimide and an amine-based compound, prepolymer of N-(2-methylphenyl)maleimide and an amine-based compound, prepolymer of N-(4-methylphenyl)maleimide and an amine-based compound, prepolymer of N-(2,6-dimethylphenyl)maleimide and an amine-based compound, prepolymer of bis(4-maleimidophenyl)methane and an amine-based compound, prepolymer of 2,2-bis(4-(4-maleimidophenoxy)-phenyl)propane and an amine-based compound, prepolymer of bis(3,5-dimethyl-4-maleimidophenyl)methane and an amine-based compound, prepolymer of bis(3-ethyl-5-methyl-4-maleimidophenyl)methane and an amine-based compound, prepolymer of bis(3,5-diethyl-4-maleimidophenyl)methane and an amine-based compound, prepolymer of an amine-based compound and maleimide containing a biphenyl structure or prepolymer of polyphenylmethane bismaleimide and an amine-based compound, but the inventive concept is not limited thereto.

A compositional ratio of the second polymer resin may be about 2 wt % to about 10 wt %, or about 3 wt % to 9 wt %, with respect to the total amount of the semiconductor encapsulation composition.

The curing agent may include an anhydride group. In examples, the curing agent may react with the first polymer resin and the second polymer resin to form a matrix. The curing agent may include for example, one or more of nadic maleic anhydride, dodecyl succinnic anhydride, maleic anhydride, succinic anhydride, methyl tetrahydro phthalic anhydride, hexahydro phthalic anhydride, tetrahydro phthalic anhydride, pyromellitic dianhydride, tetrahydro phthalic anhydride, cyclohexanedicarboxylic anhydride, methyl tetrahydro phthalic anhydride, 1,2,4-benzenetricarboxylic anhydride, benzopen one-3,3′, and/or 4,4′-tetracarboxylic dianhydride.

A compositional ratio of the curing agent may be about 2 wt % to about 10 wt %, or about 3 wt % to 9 wt %, with respect to the total amount of the semiconductor encapsulation composition.

The additive may include, as needed, a curing rate modifier, a coupling agent, and another material such as a colorant (for example, carbon black), a binder polymer, or the like.

The curing rate modifier may optimize process time by adjusting a curing reaction rate of the epoxy resin, or other polymer resin, and may improve mechanical or thermal characteristics by inducing uniform curing. For example, the curing rate modifier may include at least any one of imidazole and its derivative such as 2-methylimidazole or 2-ethyl-4-methylimidazole, an organophosphorus compound such as triphenylphosphine (TPP), tetraphenylphosphonium bromide (TPPB), a metal salt such as zinc salt, amines and an amine derivative such as triethylamine or benzyl dimethylamine, a phenolic compound such as phenolic novolac resin, or an organic acid and an anhydride such as benzoic acid or maleic anhydride.

The coupling agent may reinforce a mechanical strength, thermal conductivity, or the like by improving interfacial adhesion between a filler and a polymer resin. For example, the coupling agent may include at least one of a silane coupling agent, γ-glycidoxypropyltrimethoxysilane (GPTMS), and/or amino silane

The binder polymer may control viscosity in a packaging process, and may maintain a physical structure of, and may provide stability of the semiconductor encapsulation structure after curing the semiconductor encapsulation composition. The binding polymer may include a thermoplastic polymer. For example, the thermoplastic polymer may be at least one polymer selected from the group consisting of an acrylic polymer and a phenoxy-based polymer. The acrylic polymer may be obtained by radical polymerization using an acrylic monomer as a raw material.

According to some embodiments, for example, the acrylic monomer may be methyl(meth)acrylate, ethyl(meth)acrylate, propyl(meth)acrylate, isopropyl(meth)acrylate, butyl(meth)acrylate, isobutyl(meth)acrylate, hexyl(meth)acrylate, 2-ethylhexyl(meth)acrylate, n-octyl(meth)acrylate, isooctyl(meth)acrylate, n-nonyl(meth)acrylate, isononyl(meth)acrylate, n-decyl(meth)acrylate, isodecyl(meth)acrylate, n-dodecyl(meth)acrylate, n-tridecyl(meth)acrylate, n-tetradecyl(meth)acrylate, 2-hydroxyethyl (meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, (4-hydroxymethylcyclohexyl)methylacrylate, N-methylol(meth)acrylamide, ethyleneglycoldi(meth)acrylate, diethyleneglycoldi(meth)acrylate, tetraethyleneglycoldi(meth)acrylate, neopentylglycoldi(meth)acrylate, 1,6-hexanedioldi(meth)acrylate, trimethylolpropanetris(meth)acrylate, dipentaerythritolhexa(meth)acrylate, pentaerythritoltris(meth)acrylate, divinylbenzene, N,N′-methylenebisacrylamide.

The phenoxy-based polymer may be obtained by polymerizing a monomer such as phenoxyethylacrylate, phenoxydiethyleneglycolacrylate, phenoxypolyethyleneglycolacrylate, nonylphenoxypolyethyleneglycolacrylate, nonylphenoxypropyleneglycolacrylate, nonylphenoxyethyleneglycolacrylate, or 2-hydroxy-3-phenoxypropyl (meth)acrylate. According to some embodiments, the phenoxy-based polymer may be poly(2,6-dirauryl-1,4-phenylene)ether, poly(2,6-diphenyl-1,4-phenylene)ether, poly(2-methyl-6-phenyl-1,4-phenylene)ether, poly(2,6-dibenzyl-1,4-phenylene)ether, poly(2,6-dimethyl-1,4-phenylene)ether, poly(2,6-diethyl-1,4-phenylene)ether, poly(2-methyl-6-ethyl-1,4-phenylene)ether, poly(2,6-dipropyl-1,4-phenylene)ether, poly(2-ethyl-6-propyl-1,4-phenylene)ether, poly(2-methyl-1,4-phenylene)ether, poly(3-methyl-1,4-phenylene)ether, poly(2-methyl-6-allyl-1,4-phenylene)ether, poly(2,3,6-trimethyl-1,4-phenylene)ether, poly(2,3,5,6-tetramethyl-1,4-phenylene)ether, poly(2,5-dimethyl-1,4-phenylene)ether.

A compositional ratio of the additive may be 0 wt % to about 5 wt %, or 0 wt % to 4 wt % with respect to the total amount of the semiconductor encapsulation composition.

The first filler may have a core-shell structure. According to example embodiments, the first filler may include a plurality of particles, each particle having a core and a shell surrounding the core. An outermost surface of the first filler may have a spherical shape. The core may be a diamond particle core, in which the diamond particles have a particle diameter size of about 1 μm to about 100 μm, or about 5 μm to about 95 μm. The shell may include a high heat dissipation inorganic material. The high heat dissipation inorganic material may be at least material selected from alumina (Al₂O₃), magnesium oxide (MgO), aluminum nitride (AlN), and/or boron nitride (BN). The first filler may be formed in a method of forming a shell of the high heat dissipation inorganic material on the diamond particle, which is the core, in chemical vapor deposition, physical vapor deposition (for example, sputtering) and sol-gel processing.

According to some embodiments, the semiconductor encapsulation composition may further a second filler composed of high heat dissipation inorganic materials. For example, particles of the second filler may include alumina spheres, magnesium oxide spheres, aluminum nitride spheres, and/or boron nitride spheres. The second filler may have a particle diameter size of about 0.1 μm to about 100 μm, or about 0.5 μm to about 95 μm.

A compositional ratio of the first filler may be about 1 wt % to about 93 wt %, or about 5 wt % to about 90 wt % with respect to the total amount of the semiconductor encapsulation composition. Alternatively, a compositional ratio of a mixed filler, which is a mixture of the first filler and the second filler, may be about 1 wt % to about 93 wt %, or about 5 wt % to about 90 wt % with respect to the total amount of the semiconductor encapsulation composition. The second filler may have a smaller mass ratio than the first filler. For example, in the semiconductor encapsulation composition, the first filler may have a greater compositional ratio than the compositional ratio of the second filler with respect to the total amount of the semiconductor encapsulation composition.

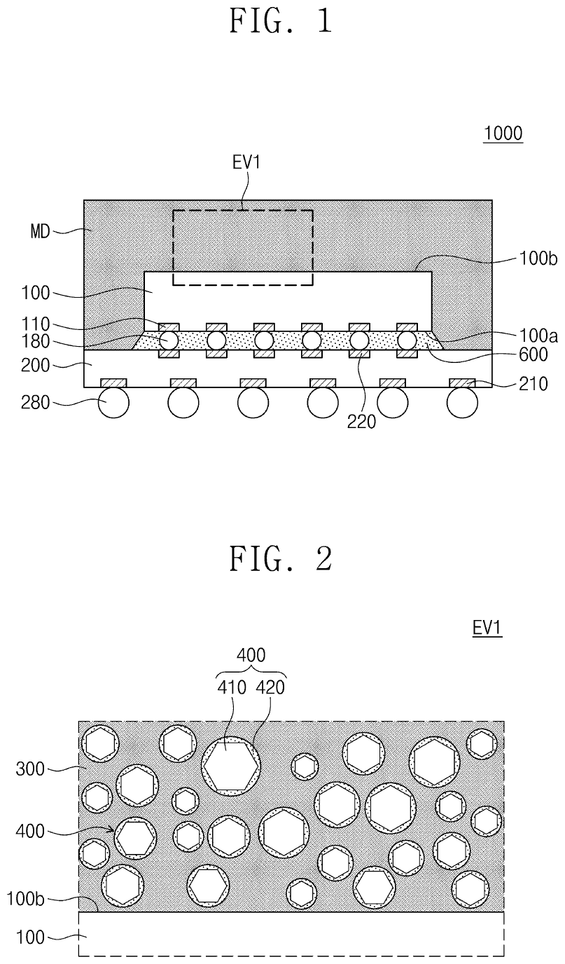

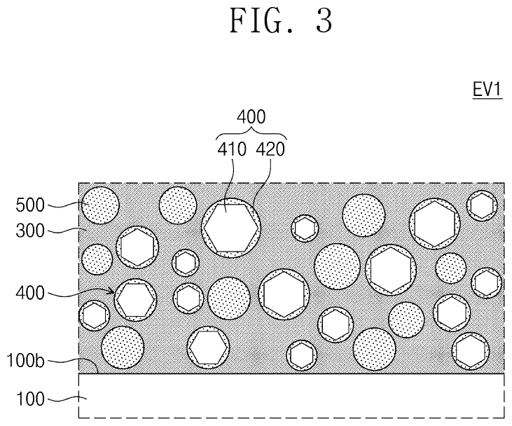

FIG. 1 is a cross-sectional view of the semiconductor package including the semiconductor encapsulation structure according to the inventive concept. FIG. 2 is an enlarged diagram of EV1 of FIG. 1. FIG. 3 is an enlarged diagram corresponding to EV1 of FIG. 1.

Referring to FIG. 1, a semiconductor package 1000 may include a package substrate 200, a semiconductor chip 100, and a semiconductor encapsulation structure MD.

The package substrate 200 may be a printed circuit board or a redistribution substrate. The package substrate 200 may include a lower substrate pad 210 and an upper substrate pad 220. An external connection terminal 280 may be disposed on the lower substrate pad 210. The external connection terminal 280 may include a conductive terminal such as a solder ball and a pillar.

The semiconductor chip 100 may be disposed on an upper surface of the package substrate 200. For example, the semiconductor chip 100 may be mounted on the package substrate 200 in a flip chip form. The semiconductor chip 100 may be a memory chip or a logic chip. The memory chip may be a volatile memory semiconductor device such as a dynamic random access memory (DRAM) and a static random access memory (SRAM), or an involatile memory semiconductor device such as a phase-change random access memory (PRAM), a magnetic random access memory (MRAM), a ferroelectric random access memory (FeRAM) and a resistive random access memory (RRAM). The logic chip may be a central processing unit (CPU) chip, a graphic processing unit (GPU) chip, an application processor (AP) chip, or an application specific integrated circuit (ASIC) chip. The semiconductor chip 100 may include a first surface 100a and a second surface 100b facing each other. The first surface 100a may correspond to an active surface on which an integrated circuit is disposed. The semiconductor chip 100 may include a chip pad 110 disposed on the first surface 100a.

An internal connection terminal 180 may be disposed between the chip pad 110 and the upper substrate pad 220. For example, the internal connection terminal 180 may be a bump. The internal connection terminal 180 may include a conductive material, such as solder.

The lower substrate pad 210, the upper substrate pad 220 and the chip pad 110 may include metal such as copper or aluminum.

The semiconductor package 1000 may further include an underfill 600. The underfill 600 may be disposed between an upper surface of the package substrate 200 and the first surface 100a of the semiconductor chip 100. The underfill 600 may cover a side surface of the internal connection terminal 180. The underfill 600 may include an epoxy material.

The semiconductor encapsulation structure MD may cover an upper surface of the package substrate 200, a side surface of the second surface 100b of the semiconductor chip 100 and a side surface of the underfill 600.

The semiconductor encapsulation structure MD may be a structure formed through a process of melting and curing the semiconductor encapsulation composition according to the inventive concept described above. The semiconductor encapsulation structure MD may include a polymer matrix 300, a first filler 400 and an additive.

The polymer matrix 300 may have a three-dimensional network structure formed by reacting the polymer resin and the curing agent of the semiconductor encapsulation composition described above. For example, the polymer matrix 300 may include an ester bond formed by reacting the epoxy group of the polymer resin and the anhydride of the curing agent. For example, the polymer matrix 300 may be formed by reacting the first polymer resin and the curing agent. According to some embodiments, the polymer matrix 300 may be formed by reacting the curing agent and a mixed polymer resin in which the first polymer resin and the second polymer resin are mixed. The additive and the first filler 400 may be provided in a form in which the first filler 400 is dispersed in the polymer matrix 300. In order to apparently illustrate configuration of the first filler 400, illustration of the additive is omitted in the drawing.

Particles of the first filler 400 may include a core 410 and a shell 420. The first filler 400 of the semiconductor encapsulation structure MD may have the same structure as the first filler of the semiconductor encapsulation composition described above. The core 410 may be a diamond particle. The shell 420 may include at least material selected from alumina (Al₂O₃), magnesium oxide (MgO), aluminum nitride (AlN), and/or boron nitride (BN). The core 410 may have a particle size of about 1 μm to about 100 μm, or 5 μm to about 95 μm, but may have an average particle size of about 10 μm to about 45 μm. According to some embodiments, the core 410 may have the average particle size of about 50 μm to about 80 μm.

Heat generated by the semiconductor chip 100 may be dissipated to the outside the chip through the first filler 400 and the polymer matrix 300 surrounding the semiconductor chip 100.

According to some embodiments, as in FIG. 3, the semiconductor encapsulation structure MD may further include a second filler 500. Particles of the second filler 500 may include alumina spheres, magnesium oxide spheres, aluminum nitride spheres, and/or boron nitride spheres. Particles of the second filler 500 may be dispersed in the polymer matrix 300. The second filler 500 may be disposed in the polymer matrix 300 in a state in which particles of the second filler 500 are mixed with particles of the first filler 400 in the same region.

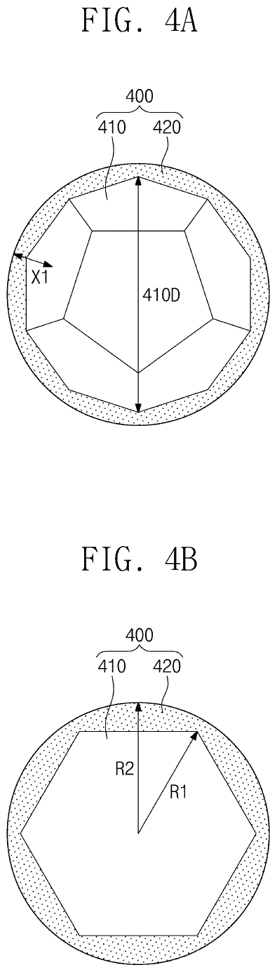

FIG. 4A is a diagram schematically illustrating the first filler. FIG. 4B is a diagram schematically illustrating a cross-section of the first filler.

As in FIGS. 4A and 4B, the core 410 may have a polygonal structure due to a diamond's own crystal structure. For example, as in FIG. 4A, the core 410 may have a shape of a dodecahedron. For example, as in FIG. 4B, a cross-section of the core 410 may have a shape of a hexagon. The core 410 may exemplarily have the shape of the dodecahedron, and the cross-section of the hexagon, and may have another shape.

As in FIG. 4B, a radius R2 of the shell 420 may be longer than a maximum radius R1 (for example, a half of a diameter) of the core 410. A volume of the shell 420 may be equal to or greater than about 33% of, and smaller than about 60% of a volume of the first filler 400. For example, a volume ratio of the shell 420 may be equal to or grater than about 40% of the volume of the first filler 400.

The shell 420 may have a surface having a spherical shape, which includes a nearly spherical shape, over a corresponding volume range. As in FIG. 4A, the greatest thickness X1 of the shell 420 may be equal to greater than about 1/10, and smaller than about ⅕ of a diameter 410D of the core 410. For example, when the core 410 has a shape of a dodecahedron and the diameter 410D of about 45 μm, the greatest thickness X1 of the shell 420 may be about 4.6 μm or about 4.3 μm. The thickness X1 of the shell 420 may be several ums, which is equal to or greater than about 1 μm and smaller than about 10 μm, or greater than about 2 μm and smaller than about 9 μm. When the thickness X1 of the core 410 is about 1 μm, the thickness X1 of the shell 420 may be equal to or greater than about 1 μm. When the thickness X1 of the shell 420 is about 0.1 μm, a surface of the shell 420 may not form a spherical shape. A targeted thermal conductivity (for example, equal to or greater than about 1000 W/m·K) of the first filler 400 may be achieved in values equal to or smaller than an upper limit of the volume ratio of the shell 420 and an upper limit of the thickness X1 of the shell 420.

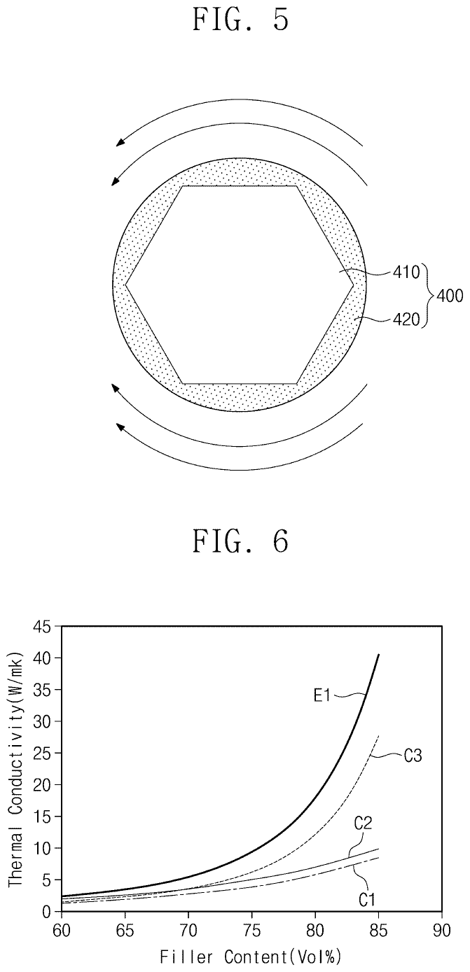

Table 1 below shows various inorganic materials and thermal conductivities thereof. FIG. 5 is a picture conceptually illustrating fluidity of the first polymer resin around the first filler.

TABLE 1

| Material | Thermal conductivity (W/m · K) |
|---|---|
| Diamond | 1,500~2,200 |
| Alumina (Al₂O₃) | 20~30 |
| Magnesium oxide (MgO) | 30~60 |
| Aluminum nitride (AlN) | 170~200 |
| Boron nitride (BN) | 50~100 |
| Silica (Glass) (SiO₂) | 1.0~1.5 |
| Lead glass (based on PbO) | 1.5~2.0 |
| Zinc glass (based on ZnO) | 1.5~3.0 |

Referring to Table 1 above, it may be seen that diamond has about ten times to about one hundred times higher thermal conductivity than other inorganic materials. When diamond particles are used as a filler, the semiconductor encapsulation structure MD may have an improved thermal conductivity to rapidly dissipate the heat of the semiconductor chip 100 outside. According to the inventive concept, because the shell has a spherical shape, when the melted semiconductor encapsulation composition covers (fills) an upper surface of the package substrate 200, the first polymer resin in the presence of the shell may have better fluidity than a fluidity in the absence of the shell. When the filler is used in a state of only diamond particles without shells, sides of the diamond particles having a polygonal shape may disturb moving of the first polymer resin in the course of filling the semiconductor encapsulation composition. In this case, a region in which the semiconductor encapsulation composition is not filled may occur, and thus a void may occur in the semiconductor encapsulation structure MD.

According to another embodiment of the inventive concept, the shell may include a high heat dissipation inorganic material having a high thermal conductivity. Alumina, magnesium oxide, aluminum nitride and boron nitride may have at least ten times higher thermal conductivity than silica, lead glass, and zinc glass, which are inorganic materials according to Comparative Examples. The shell having a higher thermal conductivity may rapidly transfer heat to the core.

For example, the diamond particle may be used as the core, and alumina may be used as the shell. In this case, when a volume ratio of the first filler becomes greater, the thermal conductivity of the first filler may decrease. Because the inorganic material used in the shell has a lower thermal conductivity than a diamond core, the thermal conductivity of the first filler may be determined by the thickness of the shell. As described in FIGS. 4A and 4B above, the thickness of the shell may be equal to or greater than about 1 μm, and about 1/10 of the diameter of the core, or a thickness of the shell equal to or greater than about 1.2 μm, and between 1/11 and 1/9 a diameter of the core. A minimum thickness of the shell is present such that a surface of the shell has a spherical shape, but the thickness of the shell may be controlled to be equal to or smaller than a certain thickness or a certain volume such that the first filler has a high thermal conductivity. For example, the thickness of the shell may be controlled in consideration of the thermal conductivity and sphericity of the first filler.

FIG. 6 is a graph illustrating thermal conductivities of semiconductor encapsulation structures formed according to Comparative Example 1, Comparative Example 2, Comparative Example 3 and Example 1.

### Example 1: E1

A semiconductor encapsulation structure was formed by curing a semiconductor encapsulation composition including a high heat dissipation resin (such as a polymer resin) and a diamond core-alumina shell (filler).

### Comparative Example 1: C1

A semiconductor encapsulation structure was formed by curing a semiconductor encapsulation composition including a normal resin (i.e., a second polymer resin), and an alumina sphere (filler).

### Comparative Example 2: C2

A semiconductor encapsulation structure was formed by curing a semiconductor encapsulation composition including a high heat dissipation resin and an alumina sphere (filler).

### Comparative Example 3: C3

A semiconductor encapsulation structure was formed by curing a semiconductor encapsulation composition including a normal resin and a diamond core-alumina shell (filler).

Referring to FIG. 6, when a filler content is small, such as about 60 vol % to about 65 vol %, thermal conductivity differences between Example 1 and Comparative Examples 1 to 3 are small, but when the filler content increases, the thermal conductivity differences significantly increase with the filler content and according to a type of the filler. In particular, it may be seen that the thermal conductivity difference dramatically increases in the filler volume ratio of about 70 vol % to about 80 vol %. In addition, it may be seen that the thermal conductivity difference between the high heat dissipation resin and the normal resin is great after forming the matrix. It may be confirmed that Example 1 has a thermal conductivity improvement effect of about 30% to about 100%, compared to Comparative Examples 1 to 3.

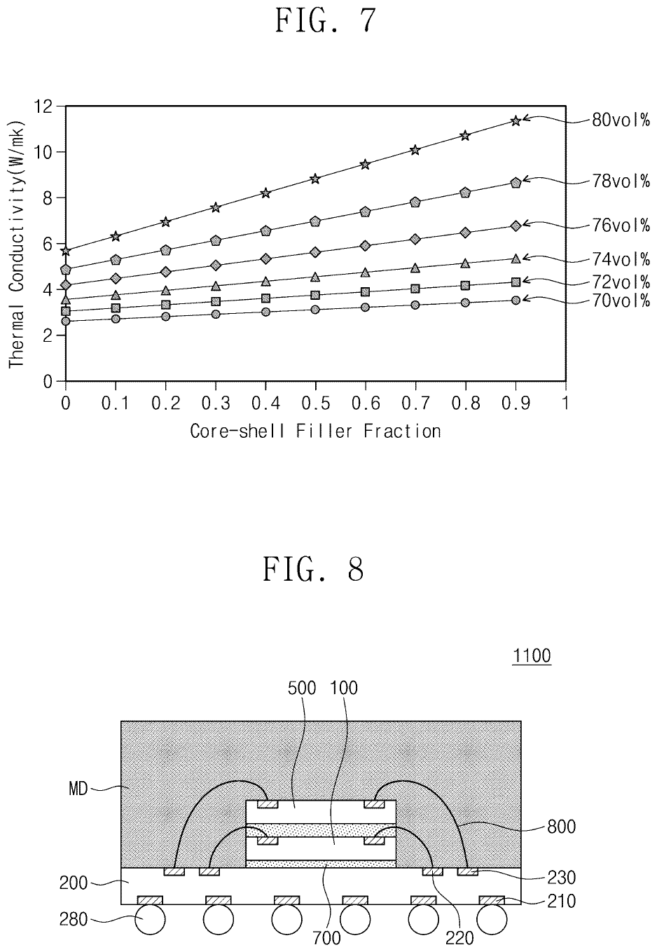

FIG. 7 is a graph illustrating the thermal conductivities of the semiconductor encapsulation structures in a case in which particles of the first filler and the second filler are used together. The diamond core-the alumina shell was used as the first filler, and the alumina sphere was used as the second filler.

Referring to FIG. 7, it may be seen that when a first filler fraction (an X axis) (for example, a mass ratio) increases, the thermal conductivities increase. In particular, it may be seen that when a volume ratio of the mixed filler in the semiconductor encapsulation structure increases from about 70 vol % to about 80 vol %, a thermal conductivity increase effect according to the first filler fraction (the X axis) is great.

FIG. 8 is a diagram illustrating the semiconductor package according to some embodiments. Except as provided below, duplicate descriptions to those made above will be omitted.

The semiconductor package 1100 may include a plurality of semiconductor chips 100 and 500. It is illustrated that semiconductor chips 100 and 500 are stacked, but according to some embodiments, the semiconductor chips 100 and 500 may be horizontally disposed. The package substrate 200 may include a first upper substrate pad 220 and a second upper substrate pad 230. Each of the first upper substrate pad 220 and the second upper substrate pad 230 may be electrically connected to the first semiconductor chip 100 and the second semiconductor chip 500, respectively, through a respective bonding wire 800. As used herein, items described as being “electrically connected” are configured such that an electrical signal can be passed from one item to the other. An adhesive layer 700 may be disposed between the semiconductor chip 100 and the package substrate 200, and between the semiconductor chip 100 and the second semiconductor chip 500. The semiconductor encapsulation structure MD may cover a side surface of the bonding wire 800.

As described above, because the semiconductor encapsulation composition includes the first filler, the high heat dissipation resin may have sufficient fluidity in a process in which the semiconductor encapsulation composition covers the bonding wires 800 and fills spaces therebetween. In addition, because the semiconductor encapsulation structure MD includes the first filler and the matrix formed from the high heat dissipation resin, heat generated by a plurality of semiconductor chips may be effectively dissipated to the outside thereof.

According to the inventive concept, a semiconductor encapsulation composition and a semiconductor encapsulation structure may include a filler including a diamond core and an inorganic material shell. A diamond filler having a polygonal shape may reduce fluidity of the semiconductor encapsulation composition, but a core-shell filler surrounded by an inorganic material shell having a surface of a sphere may improve fluidity and fillability of the semiconductor encapsulation composition to increase reliability of a semiconductor package. The diamond core may improve heat dissipation of the semiconductor encapsulation structure due to excellent thermal conductivity, and may improve performance of the semiconductor package.

Although the embodiments of the present invention have been described, it is understood that the present invention should not be limited to these embodiments but various changes and modifications can be made by one ordinary skilled in the art within the spirit and scope of the present application. Therefore, it should be understood that the embodiments described above are exemplary in all respects and the invention is not limited thereto.

What is claimed is:

1. A semiconductor encapsulation composition comprising:
a high heat dissipation resin;
a curing agent; and
a first filler comprising a plurality of particles, each particle having a diamond particle core and a shell surrounding the diamond particle core, wherein the shell includes at least one material selected from the group consisting of alumina, magnesium oxide, aluminum nitride and boron nitride.

2. The semiconductor encapsulation composition of claim 1, wherein a surface of the shell has a spherical shape.

3. The semiconductor encapsulation composition of claim 1, wherein the high heat dissipation resin has a mesogen unit, and comprises at least one of Formula 1 or Formula 2:

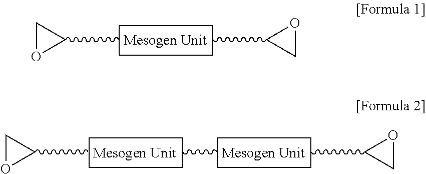

4. The semiconductor encapsulation composition of claim 3, wherein the mesogen unit comprises one of Formulae 3A to 3H, and
in Formula 3H, R is one of hydrogen (H), chlorine (Cl) or a methyl group (CH₃):

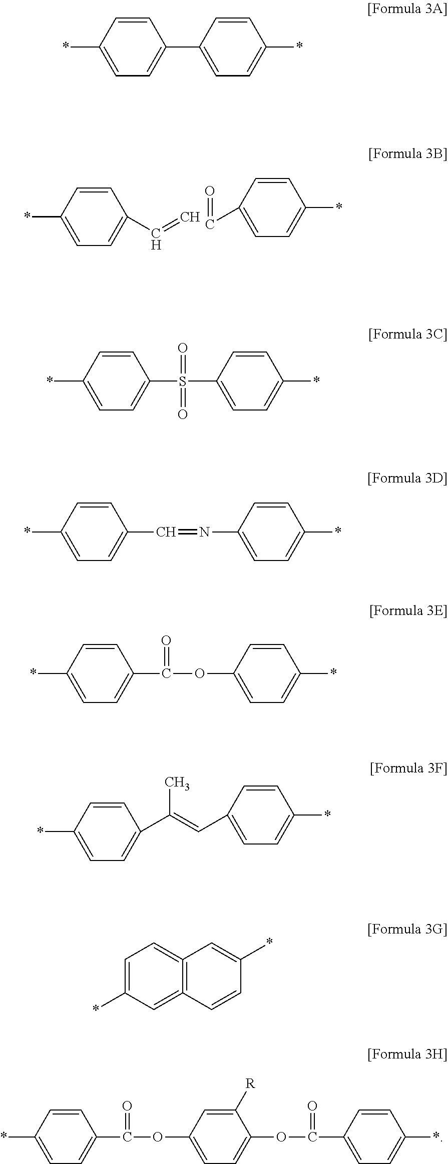

5. The semiconductor encapsulation composition of claim 1, further comprising a second filler,
wherein particles of the second filler comprise alumina spheres, magnesium oxide spheres, aluminum nitride spheres, or boron nitride spheres.

6. The semiconductor encapsulation composition of claim 5, wherein in the semiconductor encapsulation composition, a compositional ratio of the first filler is greater than a compositional ratio of the second filler, with respect to a total amount of the semiconductor encapsulation composition.

7. The semiconductor encapsulation composition of claim 1, wherein the semiconductor encapsulation composition includes 1 wt % to 93 wt % of the first filler, with respect to a total amount of the semiconductor encapsulation composition.

8. The semiconductor encapsulation composition of claim 1, wherein the semiconductor encapsulation composition includes 2 wt % to 10 wt % of the high heat dissipation resin, with respect to a total amount of the semiconductor encapsulation composition.

9. The semiconductor encapsulation composition of claim 1, wherein the curing agent comprises an anhydride group, and
the semiconductor encapsulation composition includes 2 wt % to 10 wt % of the curing agent, with respect to a total amount of the semiconductor encapsulation composition.

10. The semiconductor encapsulation composition of claim 1, further comprising an additive,
wherein the additive includes at least one additive selected from the group consisting of a curing rate modifier, a coupling agent and a binder polymer, and
the semiconductor encapsulation composition includes 0 wt % to 5 wt % of the additive with respect to a total amount of the semiconductor encapsulation composition.

11. A semiconductor encapsulation composition comprising:
a high heat dissipation resin;
a curing agent; and
a first filler comprising a plurality of particles, each particle having a diamond particle core and a shell surrounding the diamond particle core, wherein the shell includes a high heat dissipation inorganic material, and wherein a thickness of the shell is equal to or greater than 1/10 of a diameter of the diamond particle core, and is equal to or greater than 1 μm.

12. The semiconductor encapsulation composition of claim 11, wherein the high heat dissipation resin has a mesogen unit, and comprises at least one of Formula 1 or Formula 2:
the mesogen unit comprises one of Formulae 3A to 3H, and
in Formula 3H, R is one of hydrogen (H), chlorine (Cl) or a methyl group (CH₃)

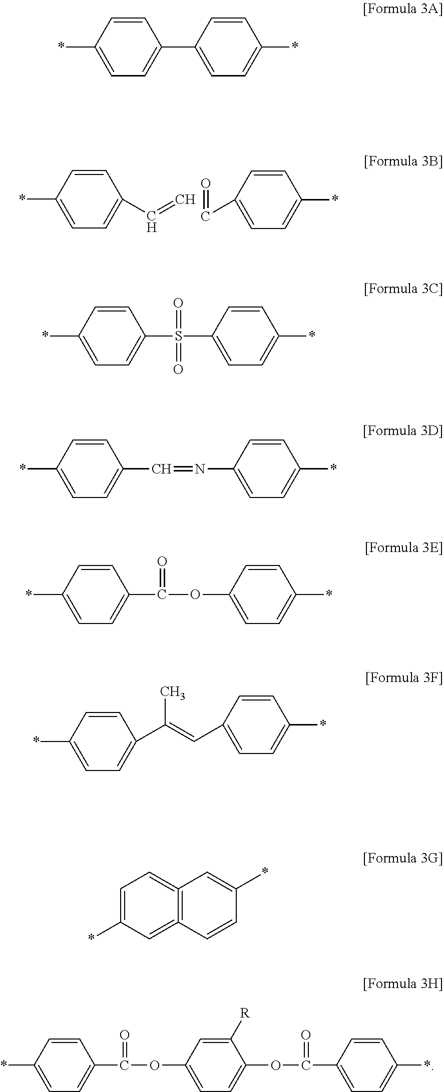

13. The semiconductor encapsulation composition of claim 11, wherein the shell has a spherical shape, and
a radius of the shell is longer than a maximum radius of the diamond particle core.

14. The semiconductor encapsulation composition of claim 11, wherein a volume of the shell is equal to or greater than 33% of a volume of the first filler.

15. The semiconductor encapsulation composition of claim 11, further comprising a second filler,
wherein particles of the second filler include the high heat dissipation inorganic material.

16. A semiconductor package comprising:
a package substrate;
a semiconductor chip on the package substrate; and
a semiconductor encapsulation composition covering the semiconductor chip,
wherein the semiconductor encapsulation composition includes:
a polymer matrix; and
a first filler dispersed in the polymer matrix, and
wherein the first filler comprises a plurality of particles, each particle having a diamond particle core and a shell surrounding the diamond particle core, wherein the shell includes at least one material selected from the group consisting of alumina, magnesium oxide, aluminum nitride and boron nitride.

17. The semiconductor package of claim 16, wherein the polymer matrix has a three-dimensional network structure including an ester bond.

18. The semiconductor package of claim 16, wherein a thickness of the shell is equal to or greater than 1/10 of a diameter of the diamond particle core.

19. The semiconductor package of claim 16, wherein a thickness of the shell is equal to or greater than 1 μm.

20. The semiconductor package of claim 16, further comprising a second filler dispersed in the polymer matrix,
wherein particles of the second filler include alumina spheres, magnesium oxide spheres, aluminum nitride spheres, or boron nitride spheres.
